(19) United States
(12) Patent Application Publication
(10) Pub. No.: US 2025/0038078 A1
(43) Pub. Date: Jan. 30, 2025

(54) BONDING STRUCTURE AND PACKAGE STRUCTURE

(71) Applicant: Advanced Semiconductor Engineering, Inc., Kaohsiung (TW)

(72) Inventors: An-Hsuan HSU, Kaohsiung (TW); Chin-Li KAO, Kaohsiung (TW)

(73) Assignee: Advanced Semiconductor Engineering, Inc., Kaohsiung (TW)

(21) Appl. No.: 18/227,892

(22) Filed: Jul. 28, 2023

(51) Int. Cl. H01L 23/498

(52) U.S. Cl. CPC H01L 23/49811

(57) ABSTRACT

A bonding structure and a package structure are provided. The bonding structure includes a first pad and a plurality of first wires. The first pad has a top surface including a first region and a second region, wherein the second region is closer to an edge of the top surface of the first pad than the first region is. The first wires are on the top surface of the first pad, wherein a number of the first wires on the first region is greater than a number of the first wires on the second region.

### BACKGROUND

### 1. Technical Field

The present disclosure relates generally to a bonding structure and a package structure.

### 2. Description of the Related Art

Conductive wires may be used for electrically connecting or bonding devices or semiconductor wafers. However, conductive wires may easily bend and protrude toward various directions, which may result in undesired short circuit and thus deteriorate the device reliability.

### SUMMARY

In one or more arrangements, a bonding structure includes a first pad and a plurality of first wires. The first pad has a top surface including a first region and a second region, wherein the second region is closer to an edge of the top surface of the first pad than the first region is. The first wires are on the top surface of the first pad, wherein a number of the first wires on the first region is greater than a number of the first wires on the second region.

In one or more arrangements, a package structure includes a first substrate, a second substrate, a plurality of first wires, and a plurality of second wires. The first substrate includes a first pad and a second pad. The second substrate includes a third pad and a fourth pad. The first wires connect the first pad to the third pad. The second wires connect the second pad to the fourth pad, wherein a wiring density distribution of the first wires is different from a wiring density distribution of the second wires.

In one or more arrangements, a package structure includes a first substrate, a second substrate, and a wire bundle structure. The first substrate includes a first pad and a second pad adjacent to the first pad. The second substrate includes a third pad. The wire bundle structure is between the first pad and the third pad The wire bundle structure includes a dense portion configured to electrically connect the first pad to the third pad and a porous portion configured to reduce an electrical transmission between the wire bundle structure and the second pad when the first pad is electrically connected to the third pad through the wire bungle structure.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of bonding structures in accordance with some arrangements of the present disclosure.

FIG. 1C is a cross-section of a package structure in accordance with some arrangements of the present disclosure.

FIG. 2A is a cross-section of a portion of a package structure in accordance with some arrangements of the present disclosure.

FIG. 2B is a top view of a portion of a package structure in accordance with some arrangements of the present disclosure.

FIG. 3A is a cross-section of a portion of a package structure in accordance with some arrangements of the present disclosure.

FIG. 3B is a top view of a portion of a package structure in accordance with some arrangements of the present disclosure.

FIG. 4A is a cross-section of a portion of a package structure in accordance with some arrangements of the present disclosure.

FIG. 4B is a top view of a portion of a package structure in accordance with some arrangements of the present disclosure.

FIG. 5A is a cross-section of a portion of a package structure in accordance with some arrangements of the present disclosure.

FIG. 5B is a top view of a portion of a package structure in accordance with some arrangements of the present disclosure.

FIG. 6A is a cross-section of a portion of a package structure in accordance with some arrangements of the present disclosure.

FIG. 6B is a top view of a portion of a package structure in accordance with some arrangements of the present disclosure.

FIG. 7 is a cross-section of a portion of a package structure in accordance with some arrangements of the present disclosure.

FIG. 8 is a cross-section of a portion of a package structure in accordance with some arrangements of the present disclosure.

FIG. 9A, FIG. 9B, FIG. 9C, and FIG. 9D illustrate various stages of an example of a method for manufacturing a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

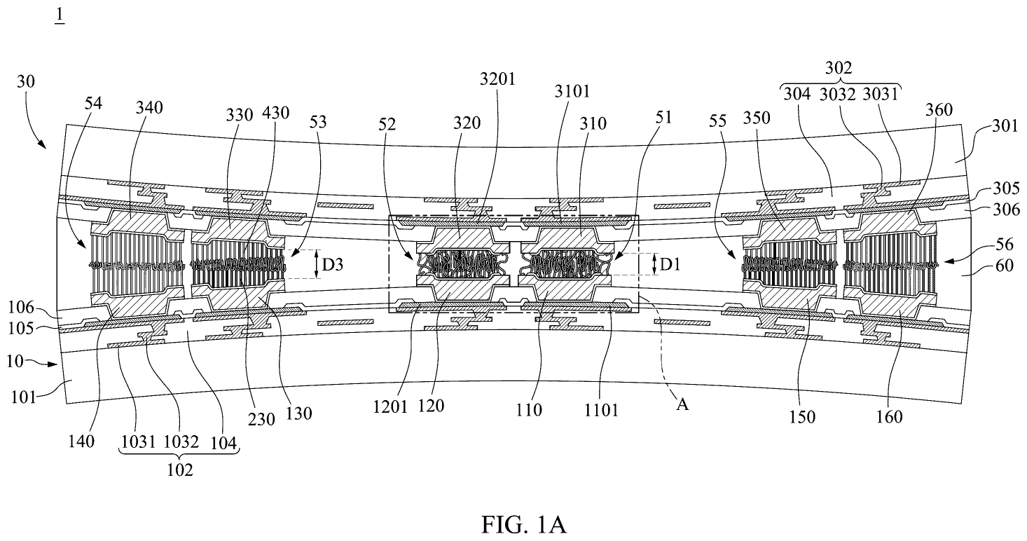

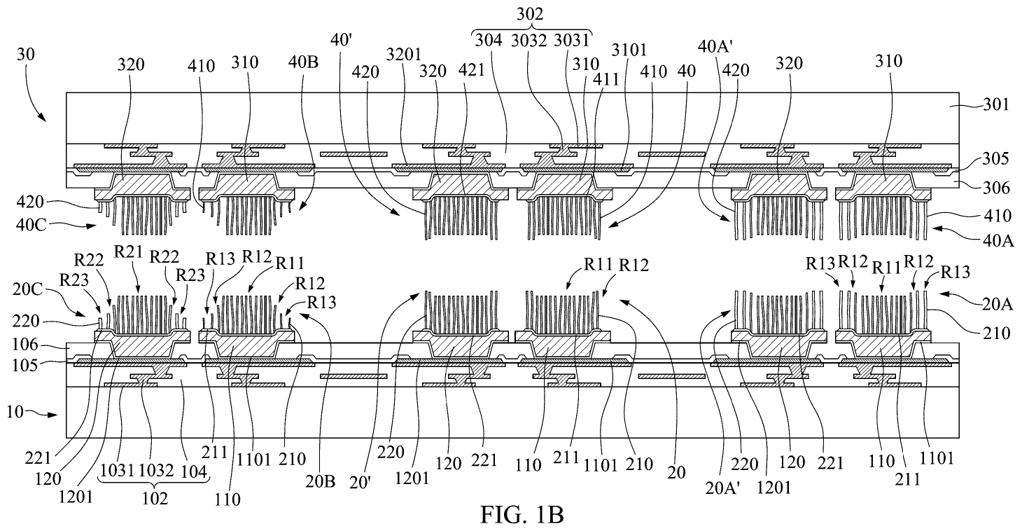

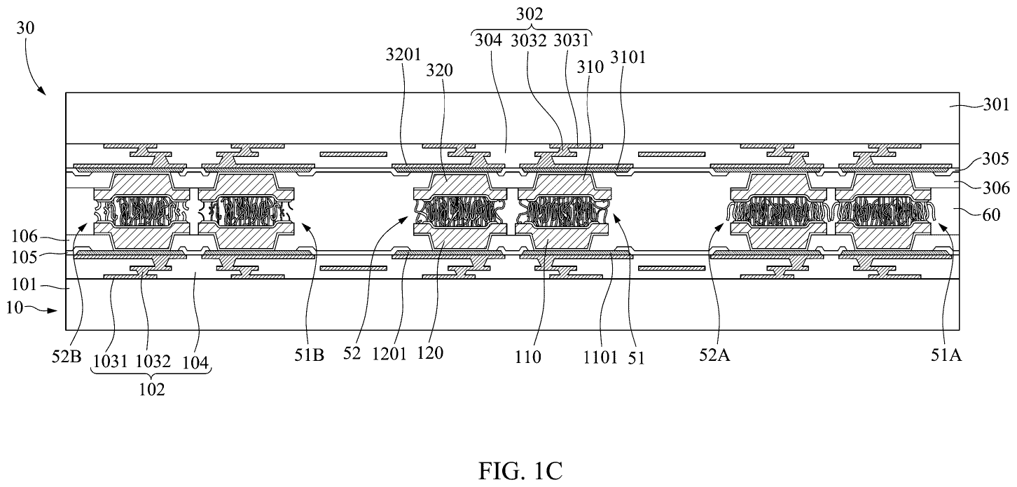

FIG. 1A is a cross-section of a package structure 1 in accordance with some arrangements of the present disclosure. The package structure 1 may include substrates 10 and 30, wire bundle structures (e.g., wire bundle structures 51, 52, 53, 54, 55, and 56), and an encapsulant 60.

The substrate 10 may include, for example, a printed circuit board, such as a paper-based copper foil laminate, a composite copper foil laminate, or a polymer-impregnated glass-fiber-based copper foil laminate. In some arrangements, the substrate 10 includes an organic substrate or a leadframe. In some arrangements, the substrate 10 includes a ceramic material or a metal plate. In some arrangements, the substrate 10 may include a two-layer substrate which includes a core layer and a conductive material and/or structure disposed on an upper surface and a bottom surface of the substrate 10.

In some arrangements, the substrate 10 includes a device layer 101, an interconnection structure 102, a passivation layer 105, and a dielectric layer 106. In some arrangements, the device layer 101 may be or include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the interconnection structure 102 includes a plurality of conductive traces 1031, a plurality of conductive vias 1032, and a dielectric layer 104. The interconnection structure 102 may include a redistribution layer (RDL) and/or a grounding element. In some arrangements, the substrate 10 may further include one or more conductive terminals (e.g., conductive pads 110, 120, 130, 140, 150, and 160). The substrate 10 may be referred to as a wiring structure, a circuit structure, a conductive structure, or a conductive carrier.

In some arrangements, the conductive pads 110 and 120 are disposed adjacent to each other, the conductive pads 130 and 140 are disposed adjacent to each other, and the conductive pads 150 and 160 are disposed adjacent to each other. In some arrangements, a distance between adjacent conductive pads may be less than about 30 μm. The conductive pads 110 and 120 may be in a center region of the substrate 10, and the conductive pads 130, 140, 150, and 160 may be in a peripheral region of the substrate 10. In some arrangements, the substrate 10 has a curved surface 10a. In some arrangements, the substrate 10 is a bent substrate. The conductive pads 110, 120, 130, 140, 150, and 160 may be referred to as conductive pillars, conductive patterns, conductive layers, or the like. The conductive pads 110, 120, 130, 140, 150, and 160 may include a conductive material such as a metal or metal alloy, for example, gold (Au), silver (Ag), aluminum (Al), copper (Cu), or an alloy thereof.

The substrate 30 may include, for example, a printed circuit board, such as a paper-based copper foil laminate, a composite copper foil laminate, or a polymer-impregnated glass-fiber-based copper foil laminate. In some arrangements, the substrate 30 includes an organic substrate or a leadframe. In some arrangements, the substrate 30 includes a ceramic material or a metal plate. In some arrangements, the substrate 30 may include a two-layer substrate which includes a core layer and a conductive material and/or structure disposed on an upper surface and a bottom surface of the substrate 10.

In some arrangements, the substrate 30 includes a device layer 301, an interconnection structure 302, a passivation layer 305, and a dielectric layer 306. In some arrangements, the device layer 301 may be or include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the interconnection structure 302 includes a plurality of conductive traces 3031, a plurality of conductive vias 3032, and a dielectric layer 304. The interconnection structure 302 may include a redistribution layer (RDL) and/or a grounding element. In some arrangements, the substrate 10 may further include one or more conductive terminals (e.g., conductive pads 310, 320, 330, 340, 350, and 360). The substrate 30 may be referred to as a wiring structure, a circuit structure, a conductive structure, or a conductive carrier.

In some arrangements, the conductive pads 310 and 320 are disposed adjacent to each other, the conductive pads 330 and 340 are disposed adjacent to each other, and the conductive pads 350 and 360 are disposed adjacent to each other. The conductive pads 310 and 320 may be in a center region of the substrate 30, and the conductive pads 330, 340, 350, and 360 may be in a peripheral region of the substrate 30. In some arrangements, the substrate 30 has a curved surface 30a. In some arrangements, the substrate 30 is a bent substrate. The conductive pads 310, 320, 330, 340, 350, and 360 may be referred to as conductive pillars, conductive patterns, conductive layers, or the like. The conductive pads 310, 320, 330, 340, 350, and 360 may include a conductive material such as a metal or metal alloy, for example, Au, Ag, Al, Cu, or an alloy thereof.

In some arrangements, a distance D1 between the conductive pad 110 and the conductive pad 310 is different from a distance D3 between the conductive pad 130 and the conductive pad 330. In some arrangements, a distance D1 between the conductive pad 110 and the conductive pad 310 is less than a distance D3 between the conductive pad 130 and the conductive pad 330. In some arrangements, the distance between opposing conductive pads increases from the center region toward the peripheral region of the package structure 1.

In some arrangements, the wire bundle structure 51 is between and connecting the conductive pads 110 and 310. In some arrangements, the wire bundle structure 52 is between and connecting the conductive pads 120 and 320. In some arrangements, the wire bundle structure 53 is between and connecting the conductive pads 130 and 330. In some arrangements, the wire bundle structure 54 is between and connecting the conductive pads 140 and 340. In some arrangements, the wire bundle structure 55 is between and connecting the conductive pads 150 and 350. In some arrangements, the wire bundle structure 56 is between and connecting the conductive pads 160 and 360. In some arrangements, the wire bundle structure includes a plurality of wires. At least some of the wires may be tangled with each other. The wires may be or include conductive wires. The wires may be or include conductive nanowires, e.g., Cu nanowires.

The encapsulant 60 may be between the substrate 10 and the substrate 30. In some arrangements, the encapsulant 60 encapsulates the wire bundle structures 51, 52, 53, 54, 55, and 56. The encapsulant 60 may be or include an underfill. The encapsulant 60 may include an epoxy resin having fillers, a molding compound (e.g., an epoxy molding compound or other molding compound), polyimide, a phenolic compound or material, a material with a silicone dispersed therein, or a combination thereof.

FIG. 1B is a cross-section of bonding structures in accordance with some arrangements of the present disclosure. In some arrangements, FIG. 1B illustrates various bonding structures 20, 40, 20A, 40A, 20B, and 40B for bonding the substrate 10 and the substrate 20. In some arrangements, FIG. 1B illustrates the bonding structures 20, 40, 20A, 40A, 20B, and 40B prior to bonding the substrate 10 and the substrate 20. Please be noted that common reference numerals are used throughout the drawings and the detailed description to indicate the same or similar elements, and the descriptions thereof are omitted hereinafter.

The bonding structure 20 may include the conductive pad 110, a conductive layer 1101, a seed layer 211, and a plurality of wires 210. In some arrangements, the conductive pad 110 has a top surface including a region R11 and a region R12 distinct from the region R11. The region R11 may be referred to as a center region, and the region R12 may be referred to as a peripheral region. In some arrangements, the region R11 may be referred to as a dense portion of the wires 210, and the region R12 may be referred to as a porous portion of the wires 210. In some arrangements, a number of the wires 210 on the region R11 is greater than a number of the wires 210 on the region R12. In some arrangements, the region R12 may be substantially free of wires.

The bonding structure 20′ may include the conductive pad 120, a conductive layer 1201, a seed layer 221, and a plurality of wires 220. The bonding structure 40 may include the conductive pad 310, a conductive layer 3101, a seed layer 311, and a plurality of wires 310. The bonding structure 40′ may include the conductive pad 320, a conductive layer 3201, a seed layer 321, and a plurality of wires 320. In some arrangements, the bonding structures 20′, 40, and 40′ have structures similar to that of the bonding structure 20.

The bonding structure 20A may include the conductive pad 110, a conductive layer 1101, a seed layer 211, and a plurality of wires 210. In some arrangements, the conductive pad 110 has a top surface including R11, R12, and R13. The region R11 may be referred to as a center region, and the region R13 may be referred to as a peripheral region. In some arrangements, the region R11 may be referred to as a dense portion of the wires 210, and the regions R12 and R13 may be referred to as a porous portion of the wires 210. In some arrangements, a number of the wires 210 on the region R11 is greater than a number of the wires 210 on the region R12, and the number of the wires 210 on the region R12 is greater than a number of the wires 210 on the region R13. In some arrangements, a density (also referred to as “a wiring density”) of the wires 210 decreases from the region R11 toward the region R13. In some arrangements, the wires 210 may have substantially the same or uniform widths. In some arrangements, the wires 210 may have substantially the same or uniform lengths. In some arrangements, the bonding structures 20A′, 40A, and 40A′ have structures similar to that of the bonding structure 20A.

The bonding structure 20B may include the conductive pad 110, a conductive layer 1101, a seed layer 211, and a plurality of wires 210. In some arrangements, a number of the wires 210 on the region R11 is greater than a number of the wires 210 on the region R12, and the number of the wires 210 on the region R12 is greater than a number of the wires 210 on the region R13. In some arrangements, a density (or a wiring density) of the wires 210 decreases from the region R11 toward the region R13. In some arrangements, the length of the wires 210 decreases from the region R11 toward the R13. In some arrangements, the width of the wires 210 decreases from the region R11 toward the region R13. In some arrangements, the bonding structure 40B has a structure similar to that of the bonding structure 20B.

The bonding structure 20C may include the conductive pad 110, a conductive layer 1101, a seed layer 211, and a plurality of wires 210. In some arrangements, a number of the wires 210 on the region R11 is greater than a number of the wires 210 on the region R12, and the number of the wires 210 on the region R12 is greater than a number of the wires 210 on the region R13. In some arrangements, a density of the wires 210 decreases from the region R11 toward the region R13. In some arrangements, the length of the wires 210 decreases from the region R11 toward the R13. In some arrangements, the width of the wires 210 increases from the region R11 toward the region R13. In some arrangements, the bonding structure 40C has a structure similar to that of the bonding structure 20C.

FIG. 1C is a cross-section of a package structure 1′ in accordance with some arrangements of the present disclosure. The structure illustrated in FIG. 1C is similar to that in FIG. 1A, and the differences therebetween are described as follows. In some arrangements, FIG. 1C illustrates a bonded package structure formed from the bonding structures as shown in FIG. 1B.

In some arrangements, the package structure 1′ includes the substrates 10 and 30, wire bundle structures 51, 52, 51A, 52A, 51B, and 52B, and the encapsulant 60. In some arrangements, the wire bundle structure 51 is formed by bonding the bonding structure 20 and 40 illustrated in FIG. 1B. In some arrangements, the wire bundle structure 52 is formed by bonding the bonding structure 20′ and 40′ illustrated in FIG. 1B. In some arrangements, the wire bundle structure 51A is formed by bonding the bonding structure 20A and 40A illustrated in FIG. 1B. In some arrangements, the wire bundle structure 52A is formed by bonding the bonding structure 20A′ and 40A′ illustrated in FIG. 1B. In some arrangements, the wire bundle structure 51B is formed by bonding the bonding structure 20B and 40B illustrated in FIG. 1B. In some arrangements, the wire bundle structure 52B is formed by bonding the bonding structure 20C and 40C illustrated in FIG. 1B.

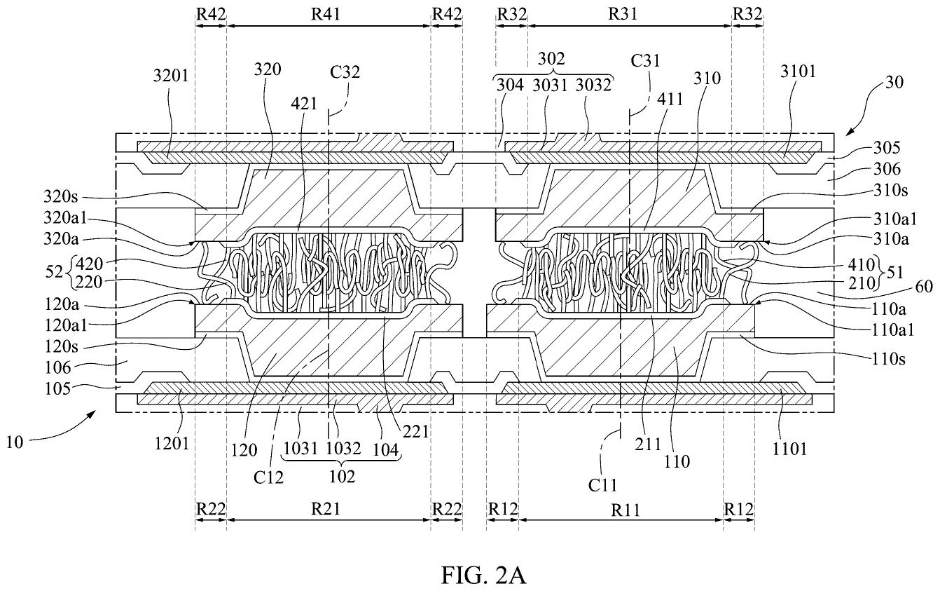

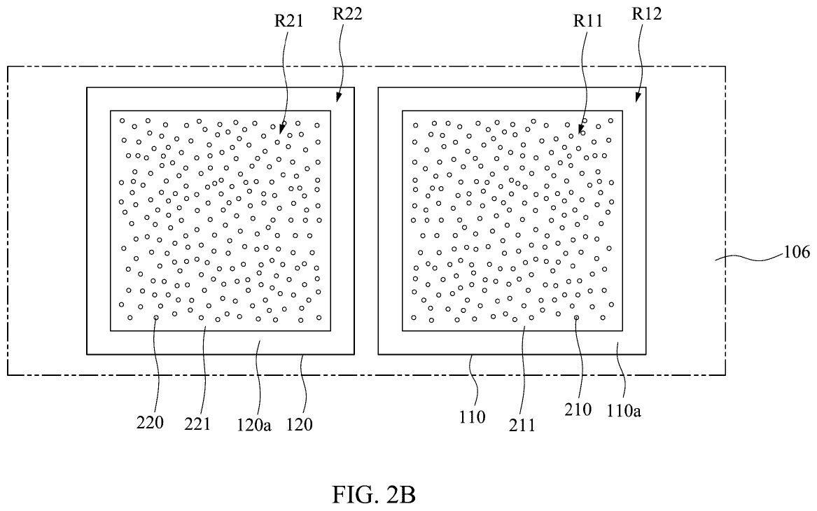

FIG. 2A is a cross-section of a portion of a package structure in accordance with some arrangements of the present disclosure. FIG. 2B is a top view of a portion of a package structure in accordance with some arrangements of the present disclosure. In some arrangements, FIG. 2A illustrates a cross-section of the structure of the portion A of the package structure 1 illustrated in FIG. 1A. In some arrangements, FIG. 2B illustrates a top view of the structure of the portion A of the package structure 1 illustrated in FIG. 1A. In some arrangements, the structure illustrated in FIGS. 2A-2B may be formed from the bonding structures 20, 20′, 40, and 40′ as shown in FIG. 1B.

In some arrangements, the conductive pad 110 has a top surface 110a including a region R11 and a region R12 distinct from the region R11. In some arrangements, the region R12 is closer to an edge 110al of the top surface 110a of the conductive pad 110 than the region R11 is. The region R11 may be referred to as a center region, and the region R12 may be referred to as a peripheral region. In some arrangements, the conductive pad 110 is electrically connected to the conductive trace 1031 through a conductive layer 1101 (also referred to as “a conductive pad”). In some arrangements, a seed layer 110s is between the conductive layer 1101 and the conductive pad 110. In some arrangements, a seed layer 211 is between the conductive pad 110 and the wire bundle structure 51. The conductive layer 1101 may include a conductive material such as a metal or metal alloy, for example, Au, Ag, Al, Cu, or an alloy thereof. The seed layers 110s and 211 may independently include, for example, titanium (Ti), Cu, nickel (Ni), another metal, or an alloy (such as a titanium-tungsten alloy (TiW)).

In some arrangements, the conductive pad 310 has a top surface 310a including a region R31 and a region R32 distinct from the region R31. In some arrangements, the region R32 is closer to an edge 310al of the top surface 310a of the conductive pad 310 than the region R31 is. The region R31 may be referred to as a center region, and the region R32 may be referred to as a peripheral region. In some arrangements, the conductive pad 310 is electrically connected to the conductive trace 3031 through a conductive layer 3101 (also referred to as “a conductive pad”). In some arrangements, a seed layer 310s is between the conductive layer 3101 and the conductive pad 310. In some arrangements, a seed layer 411 is between the conductive pad 310 and the wire bundle structure 51. The conductive layer 3101 may include a conductive material such as a metal or metal alloy, for example, Au, Ag, Al, Cu, or an alloy thereof. The seed layers 310s and 411 may independently include, for example, Ti, Cu, Ni, another metal, or an alloy (such as a TiW alloy). In some arrangements, a central axis C11 of the conductive pad 110 is misaligned with a central axis C31 of the conductive pad 310.

In some arrangements, the wire bundle structure 51 includes a dense portion configured to electrically connect the conductive pad 110 to the conductive pad 310. In some arrangements, the wire bundle structure 51 includes a porous portion configured to prevent short circuit between the conductive pad 110 and the conductive pad 120. In some arrangements, the wire bundle structure 51 includes a porous portion configured to reduce an electrical transmission between the wire bundle structure 51 and the pad 120 when the pad 110 is electrically connected to the pad 310 through the wire bungle structure 51. In some arrangements, the wire bundle structure 51 includes a plurality of wires 210 and 410. In some arrangements, the wires 210 and 410 on the region R11 and/or the region R31 are the dense portion of the wire bundle structure 51, and the wires 210 and 410 on the region R12 and/or the region R32 are the porous portion of the wire bundle structure 51. In some arrangements, a density (or a wiring density) of the dense portion is greater than a density (or a wiring density) of the porous portion. In some arrangements, the porous portion of the wire bundle structure 51 is between the dense portion of the wire bundle structure 51 and the conductive pad 120. In some arrangements, a boundary of the dense portion of the wire bundle structure 51 is recessed from the edge 110al of the conductive pad 110 by at least 20% of a width of the conductive pad 110. In some arrangements, the porous portion of the wire bundle structure 51 is on a peripheral region (e.g., the region R12) of the top surface 110a of the conductive pad 110. In some arrangements, the dense portion (e.g., the region R11) of the wire bundle structure 51 covers at least 50% of an area of the top surface 110a of the conductive pad 110.

In some arrangements, the wires 210 and 410 connect the conductive pad 110 to the conductive pad 310. In some arrangements, the wires 210 are on the top surface 110a of the conductive pad 110, and a number of the wires 210 on the region R11 is greater than a number of the wires 210 on the region R12. In some arrangements, the wires 210 have a density on the region R11 (or a first wiring density) and a density on the region R12 (or a second wiring density) that is less than the density of the wires 210 on the region R11 (or the first wiring density). In some arrangements, a density (or a wiring density) of the wires 210 decreases from the region R11 toward the region R12. In some arrangements, the region R12 surrounds the region R11. In some arrangements, the wires 210 include at least a curved portion (e.g., at least one of the wires 210) extending from the region R11 to the region R12. In some arrangements, the wires 210 may have a length from about 1 μm to about 10 μm. In some arrangements, one or more of the wires 210 may be bent or tilted with respect to the top surface 110a of the conductive pad 110. In some arrangements, one or more of the wires 210 may contact the seed layer 411.

In some arrangements, the wires 410 connect the conductive pad 310 to the wires 210. In some arrangements, the wires 410 are on the top surface 310a of the conductive pad 310, and a number of the wires 410 on the region R31 is greater than a number of the wires 410 on the region R32. In some arrangements, the wires 410 have a density on the region R31 (or a third wiring density) and a density on the region R32 (or a fourth wiring density) that is less than the density of the wires 410 on the region R31 (or the third wiring density). In some arrangements, a density (or a wiring density) of the wires 410 decreases from the region R31 toward the region R32. In some arrangements, the region R32 surrounds the region R31. In some arrangements, the wires 410 may have a length from about 1 μm to about 10 μm. In some arrangements, one or more of the wires 410 may be bent or tilted with respect to the top surface 310a of the conductive pad 310. In some arrangements, one or more of the wires 410 may contact the seed layer 211.

In some arrangements, the conductive pad 120 is adjacent to the conductive pad 110. In some arrangements, the conductive pad 120 has a top surface 120a including a region R21 and a region R22 distinct from the region R21. In some arrangements, the region R22 is closer to an edge 120al of the top surface 120a of the conductive pad 120 than the region R21 is. The region R21 may be referred to as a center region, and the region R22 may be referred to as a peripheral region. In some arrangements, the conductive pad 120 is electrically connected to the conductive trace 1031 through a conductive layer 1201 (also referred to as “a conductive pad”). In some arrangements, a seed layer 120s is between the conductive layer 1201 and the conductive pad 120. In some arrangements, a seed layer 221 is between the conductive pad 120 and the wire bundle structure 52. The conductive layer 1201 may include a conductive material such as a metal or metal alloy, for example, Au, Ag, Al, Cu, or an alloy thereof. The seed layers 120s and 221 may independently include, for example, Ti, Cu, Ni, another metal, or an alloy (such as a TiW alloy).

In some arrangements, the conductive pad 320 is adjacent to the conductive pad 310. In some arrangements, the conductive pad 320 has a top surface 320a including a region R41 and a region R42 distinct from the region R41. In some arrangements, the region R42 is closer to an edge 320al of the top surface 320a of the conductive pad 320 than the region R41 is. The region R41 may be referred to as a center region, and the region R42 may be referred to as a peripheral region. In some arrangements, the conductive pad 320 is electrically connected to the conductive trace 3031 through a conductive layer 3201 (also referred to as “a conductive pad”). In some arrangements, a seed layer 320s is between the conductive layer 3201 and the conductive pad 320. In some arrangements, a seed layer 421 is between the conductive pad 320 and the wire bundle structure 52. The conductive layer 3201 may include a conductive material such as a metal or metal alloy, for example, Au, Ag, Al, Cu, or an alloy thereof. The seed layers 320s and 421 may independently include, for example, Ti, Cu, Ni, another metal, or an alloy (such as a TiW alloy). In some arrangements, a central axis C12 of the conductive pad 120 is substantially aligned with a central axis C32 of the conductive pad 320.

In some arrangements, the wire bundle structure 52 includes a dense portion configured to electrically connect the conductive pad 120 to the conductive pad 320. In some arrangements, the wire bundle structure 52 includes a porous portion configured to prevent short circuit between the conductive pad 310 and the conductive pad 320. In some arrangements, the wire bundle structure 52 includes a plurality of wires 220 and 420. In some arrangements, the wires 220 and 420 on the region R21 and/or the region R41 are the dense portion of the wire bundle structure 52, and the wires 220 and 420 on the region R22 and/or the region R42 are the porous portion of the wire bundle structure 52. In some arrangements, a density (or a wiring density) of the dense portion is greater than a density (or a wiring density) of the porous portion. In some arrangements, the porous portion of the wire bundle structure 52 is between the dense portion of the wire bundle structure 52 and the conductive pad 110. In some arrangements, a boundary of the dense portion of the wire bundle structure 52 is recessed from the edge 120al of the conductive pad 120 by at least 20% of a width of the conductive pad 120. In some arrangements, the porous portion of the wire bundle structure 52 is on a peripheral region (e.g., the region R22) of the top surface 120a of the conductive pad 120. In some arrangements, the dense portion (e.g., the region R21) of the wire bundle structure 52 covers at least 50% of an area of the top surface 120a of the conductive pad 120.

In some arrangements, the wires 220 and 420 connect the conductive pad 120 to the conductive pad 320. In some arrangements, the wires 220 are on the top surface 120a of the conductive pad 120, and a number of the wires 220 on the region R21 is greater than a number of the wires 220 on the region R22. In some arrangements, the wires 220 have a density on the region R21 (or a fifth wiring density) and a density on the region R22 (or a sixth wiring density) that is less than the density of the wires 220 on the region R21 (or the fifth wiring density). In some arrangements, a density (or a wiring density) of the wires 220 decreases from the region R21 toward the region R22. In some arrangements, the region R22 surrounds the region R21. In some arrangements, the wires 210 include at least a curved portion (e.g., at least one of the wires 210), and the wires 220 include at least a curved portion (e.g., at least one of the wires 220) that is free from contacting the curved portion of the wires 210. In some arrangements, the wires 220 may have a length from about 1 μm to about 10 μm. In some arrangements, one or more of the wires 220 may be bent or tilted with respect to the top surface 120a of the conductive pad 120. In some arrangements, one or more of the wires 220 may contact the seed layer 421.

In some arrangements, the wires 420 connect the conductive pad 320 to the wires 220. In some arrangements, the wires 420 are on the top surface 320a of the conductive pad 320, and a number of the wires 420 on the region R41 is greater than a number of the wires 420 on the region R42. In some arrangements, the wires 420 have a density on the region R41 (or a seventh wiring density) and a density on the region R42 (or an eighth wiring density) that is less than the density of the wires 420 on the region R41 (or the seventh wiring density). In some arrangements, a density (or a wiring density) of the wires 420 decreases from the region R41 toward the region R42. In some arrangements, the region R42 surrounds the region R41. In some arrangements, the wires 420 may have a length from about 1 μm to about 10 μm. In some arrangements, one or more of the wires 420 may be bent or tilted with respect to the top surface 320a of the conductive pad 320. In some arrangements, one or more of the wires 420 may contact the seed layer 221.

In some arrangements, referring to FIG. 1A and FIGS. 2A-2B, the wire bundle structure 53 includes a plurality of wires 230 and 430. In some arrangements, the wires 230 and 430 connect the conductive pad 130 to the conductive pad 330. In some arrangements, the wires 230 and 430 may have a length from about 1 μm to about 10 μm. In some arrangements, a density distribution (also referred to as “a wiring density distribution”) of the wires 210 and 410 is different from a density distribution of the wires 230 and 430. In some arrangements, a density of the wires 230 and 430 is substantially uniform. In some arrangements, a width distribution of the wires 210 and 410 may be the same as or different from a width distribution of the wires 230 and 430. In some arrangements, a length distribution of the wires 210 and 410 may be the same as or different from a length distribution of the wires 230 and 430. In some arrangements, the wire bundle structure 54, 55, and 56 have structures similar to that of the wire bundle structure 53, and the descriptions thereof are omitted hereinafter.

In some arrangements, referring to FIG. 2B, the region R12 of the top surface 110a of the conductive pad 110 may be free of the wires 210.

According to some arrangements of the present disclosure, the number of the wires on the peripheral region (e.g., the region R12) of the conductive pad is less than the number of the wires on the center region (e.g., the region R11) of the conductive pad, which means that there are fewer wires on the peripheral region adjacent to the edges of the conductive pad, thus fewer wires may bend and protrude out of edges of the conductive pads to contact the wires from an adjacent conductive pad. Therefore, short circuit resulted from bent wires from adjacent conductive pads contacting each other can be prevented.

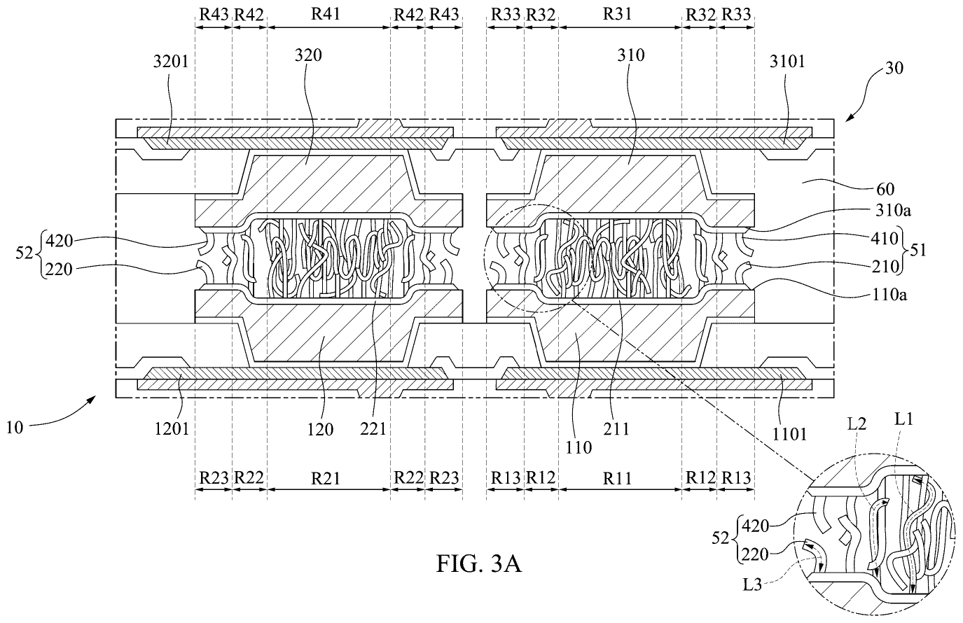

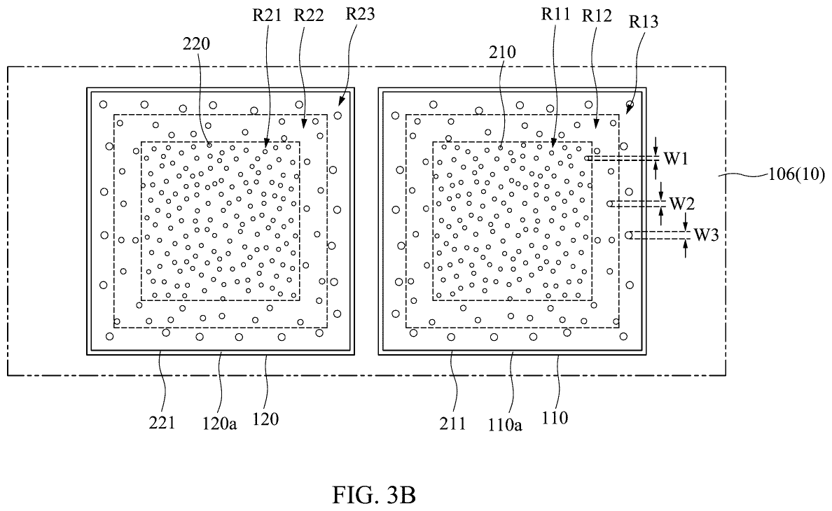

FIG. 3A is a cross-section of a portion of a package structure in accordance with some arrangements of the present disclosure. FIG. 3B is a top view of a portion of a package structure in accordance with some arrangements of the present disclosure. In some arrangements, FIG. 3A illustrates a cross-section of the structure of the portion A of the package structure 1 illustrated in FIG. 1A. In some arrangements, FIG. 3B illustrates a top view of the structure of the portion A of the package structure 1 illustrated in FIG. 1A. The structures illustrated in FIG. 3A and FIG. 3B are similar to that in FIG. 2A and FIG. 2B, and the differences therebetween are described as follows. In some arrangements, the structure illustrated in FIGS. 3A-3B may be formed from the bonding structures 20C and 40C as shown in FIG. 1B.

In some arrangements, the top surface 110a of the conductive pad 110 has regions R11, R12, and R13. The region R11 may be referred to as a center region, and the region R13 may be referred to as a peripheral region. In some arrangements, the top surface 310a of the conductive pad 310 has regions R31, R32, and R33. The region R31 may be referred to as a center region, and the region R33 may be referred to as a peripheral region. In some arrangements, the wires 210 and 410 on the region R11 and/or the region R31 are the dense portion of the wire bundle structure 51, and the wires 210 and 410 on the region R12 and R13 and/or the region R32 and R33 are the porous portion of the wire bundle structure 51.

In some arrangements, a number of the wires 210 on the region R11 is greater than a number of the wires 210 on the region R12, and the number of the wires 210 on the region R12 is greater than a number of the wires 210 on the region R13. In some arrangements, a density of the wires 210 decreases from the region R11 toward the region R13. In some arrangements, a number of the wires 410 on the region R31 is greater than a number of the wires 410 on the region R32, and the number of the wires 410 on the region R32 is greater than a number of the wires 410 on the region R33. In some arrangements, a density of the wires 410 decreases from the region R31 toward the region R33. In some arrangements, referring to FIGS. 1 and 3A-3B, a density distribution (or a wiring density distribution) of the wires 210 and 410 is different from a density distribution of the wires 230 and 430.

In some arrangements, referring to FIG. 3A, a length L3 of the wires 210 on the region R13 is less than a length L2 of the wires 210 on the region R12, and the length L2 of the wires 210 on the region R12 is less than a length L1 of the wires 210 on the region R11. In some arrangements, the length of the wires 210 decreases from the region R11 toward the R13. In some arrangements, referring to FIGS. 1 and 3A, a length distribution of the wires 210 and 410 may be different from a length distribution of the wires 230 and 430. In some arrangements, referring to FIG. 3B, a width W3 of the wires 210 on the region R13 is greater than a width W2 of the wires 210 on the region R12, and the width W2 of the wires 210 on the region R12 is greater than a width W1 of the wires 210 on the region R11. In some arrangements, the width of the wires 210 increases from the region R11 toward the region R13. In some arrangements, referring to FIGS. 1 and 3B, a width distribution of the wires 210 and 410 may be the different from a width distribution of the wires 230 and 430. In some arrangements, a portion of the wires 410 is spaced apart from a portion of the wires 210. In some arrangements, a portion of the wires 410 is over and spaced apart from a portion of the wires 210.

According to some arrangements of the present disclosure, the widths of the wires on the peripheral region (e.g., the region R12 and/or R13) of the conductive pad are greater than the widths of the wires on the center region (e.g., the region R11) of the conductive pad. The wires having greater widths have relatively large rigidity and thus are less prone to bending when a pressure is applied from above in a bonding operation.

In addition, according to some arrangements of the present disclosure, the wires on the peripheral region have greater widths, and thus the wires on the peripheral region can have relatively large rigidity and are less prone to bending. Therefore, even the wires on the peripheral region may have relatively large lengths, the wires can hold from being bent, and thus the wires on the peripheral region can be prevented from tipping over and/or protruding out of edges of the conductive pads. Therefore, short circuit resulted from bent wires protruding from adjacent conductive pads contacting each other can be prevented.

Moreover, according to some arrangements of the present disclosure, the lengths of the wires on the peripheral region (e.g., the region R13) of the conductive pad are less than the lengths of the wires on the center region (e.g., the region R11) of the conductive pad, and thus the wires on the peripheral region can be prevented from bending and protruding out of edges of the conductive pads. Therefore, short circuit resulted from bent wires protruding from adjacent conductive pads contacting each other can be prevented.

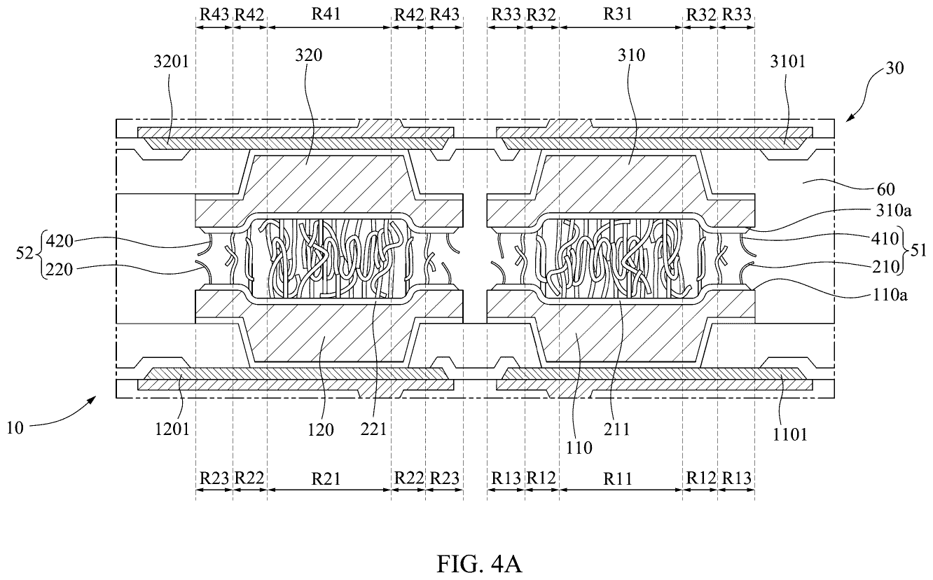

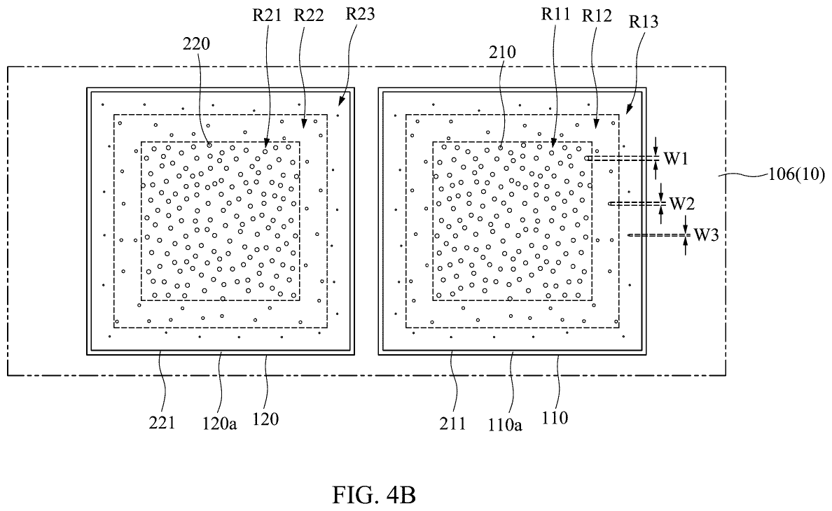

FIG. 4A is a cross-section of a portion of a package structure in accordance with some arrangements of the present disclosure. FIG. 4B is a top view of a portion of a package structure in accordance with some arrangements of the present disclosure. In some arrangements, FIG. 4A illustrates a cross-section of the structure of the portion A of the package structure 1 illustrated in FIG. 1A. In some arrangements, FIG. 4B illustrates a top view of the structure of the portion A of the package structure 1 illustrated in FIG. 1A. The structures illustrated in FIG. 4A and FIG. 4B are similar to that in FIG. 3A and FIG. 3B, and the differences therebetween are described as follows. In some arrangements, the structure illustrated in FIGS. 4A-4B may be formed from the bonding structures 20B and 40B as shown in FIG. 1B.

In some arrangements, referring to FIG. 4B, a width W3 of the wires 210 on the region R13 is less than a width W2 of the wires 210 on the region R12, and the width W2 of the wires 210 on the region R12 is less than a width W1 of the wires 210 on the region R11. In some arrangements, the width of the wires 210 decreases from the region R11 toward the region R13.

According to some arrangements of the present disclosure, the widths of the wires on the center region (e.g., the region R11) of the conductive pad are greater than the widths of the wires on the peripheral region (e.g., the region R13) of the conductive pad. The wires on the center region may be referred to the dense portion of the wire bundle structure that is configured to electrically connect opposing conductive pads. Therefore, the electrical conductivity of the dense portion of the wire bundle structure can be increased, and thus the electrical performance of the package structure can be improved.

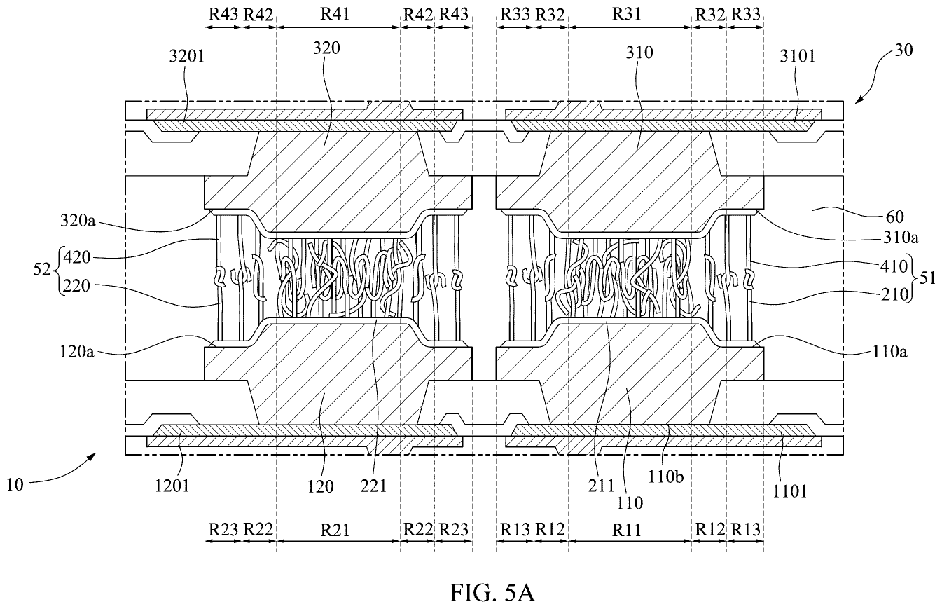

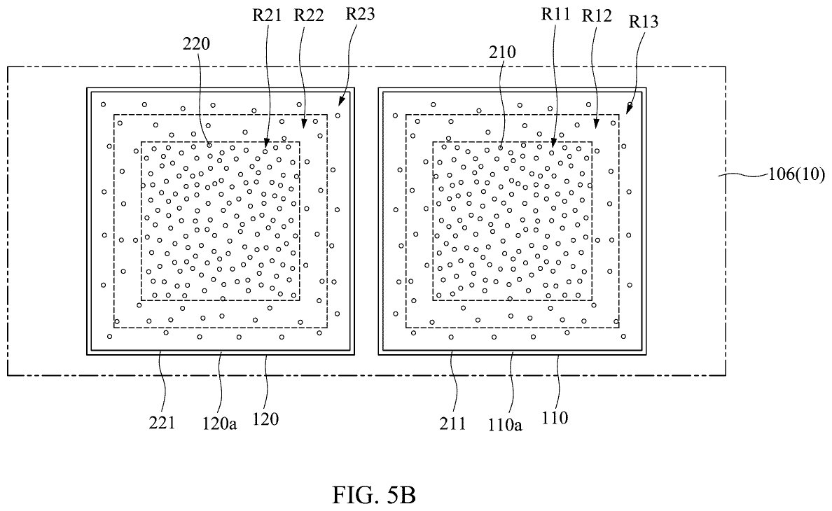

FIG. 5A is a cross-section of a portion of a package structure in accordance with some arrangements of the present disclosure. FIG. 5B is a top view of a portion of a package structure in accordance with some arrangements of the present disclosure. In some arrangements, FIG. 5A illustrates a cross-section of the structure of the portion A of the package structure 1 illustrated in FIG. 1A. In some arrangements, FIG. 5B illustrates a top view of the structure of the portion A of the package structure 1 illustrated in FIG. 1A. The structures illustrated in FIG. 5A and FIG. 5B are similar to that in FIG. 3A and FIG. 3B, and the differences therebetween are described as follows.

In some arrangements, an elevation of the region R11 is higher than an elevation of the region R12 with respect to a bottom surface 110b of the conductive pad 110. In some arrangements, an elevation of the region R12 is higher than an elevation of the region R13 with respect to a bottom surface 110b of the conductive pad 110. In some arrangements, the wires 210 have a substantially uniform length. In some arrangements, the wires 210 have a substantially uniform width. In some arrangements, the distance between the conductive pad 110 and the conductive pad 310 increases from a center region (e.g., the region R11) toward a peripheral region (e.g., the region R13) of the conductive pad 110.

According to some arrangements of the present disclosure, the distance between opposing conductive pads increases from the center region toward the peripheral region of the conductive pad. As such, even the wires on the peripheral region may have relatively large lengths, the relatively large distance between the opposing conductive pads at the peripheral region provides a sufficient tolerance or spacing for the wires to extend between the opposing conductive pads without bending or tilting, and thus the wires on the peripheral region can be prevented from tipping over and/or protruding out of edges of the conductive pads. Therefore, short circuit resulted from bent wires protruding from adjacent conductive pads contacting each other can be prevented.

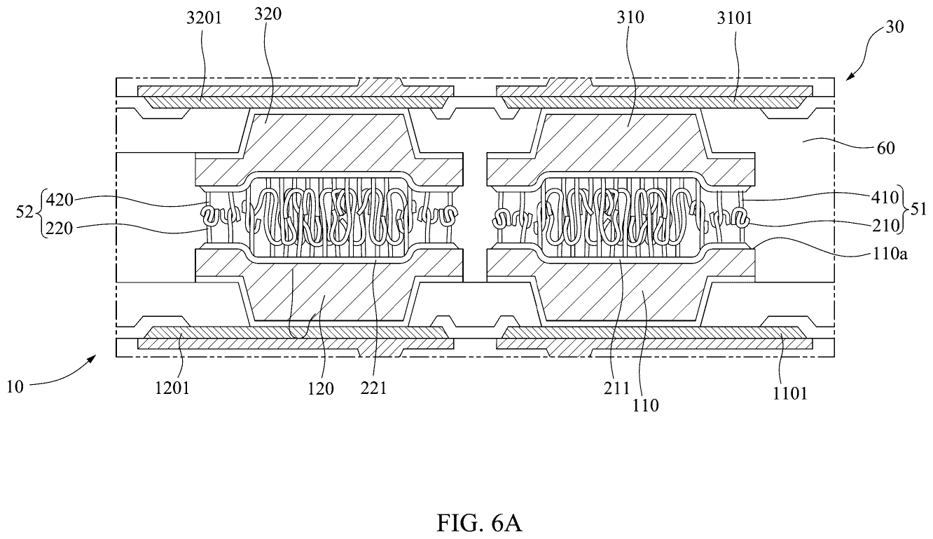

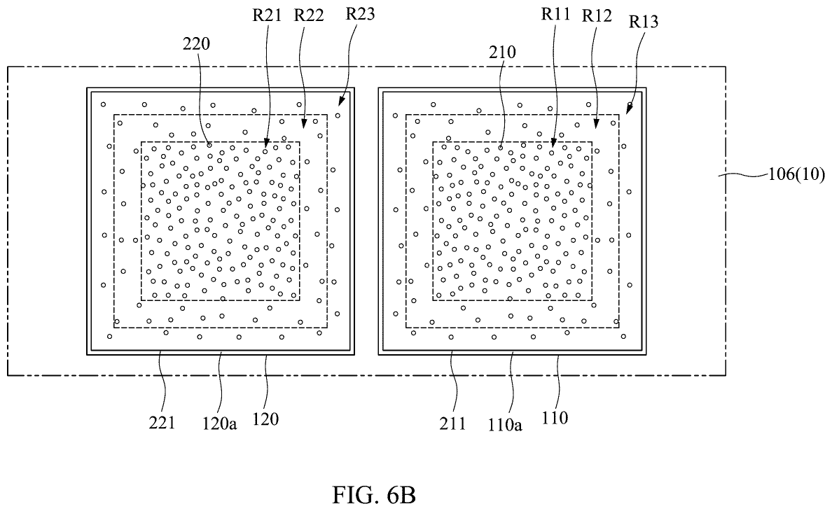

FIG. 6A is a cross-section of a portion of a package structure in accordance with some arrangements of the present disclosure. FIG. 6B is a top view of a portion of a package structure in accordance with some arrangements of the present disclosure. In some arrangements, FIG. 6A illustrates a cross-section of the structure of the portion A of the package structure 1 illustrated in FIG. 1A. In some arrangements, FIG. 6B illustrates a top view of the structure of the portion A of the package structure 1 illustrated in FIG. 1A. The structures illustrated in FIG. 6A and FIG. 6B are similar to that in FIG. 3A and FIG. 3B, and the differences therebetween are described as follows.

In some arrangements, the lengths of the wires 210, 220, 410, and 420 decreases from a center region toward a peripheral region of the corresponding conductive pad. In some arrangements, the lengths of the wires are less than a distance between the opposing conductive pads. In some arrangements, the wires 210 are not bent or tilted with respect to the top surface 110a of the conductive pad 110. In some arrangements, the wires 210 are spaced apart from the seed layer 411. In some arrangements, the wires 220 are not bent or tilted with respect to the top surface 120a of the conductive pad 120. In some arrangements, the wires 220 are spaced apart from the seed layer 421. In some arrangements, the wires 410 are not bent or tilted with respect to the top surface 310a of the conductive pad 310. In some arrangements, the wires 410 are spaced apart from the seed layer 211. In some arrangements, the wires 420 are not bent or tilted with respect to the top surface 320a of the conductive pad 320. In some arrangements, the wires 420 are spaced apart from the seed layer 221.

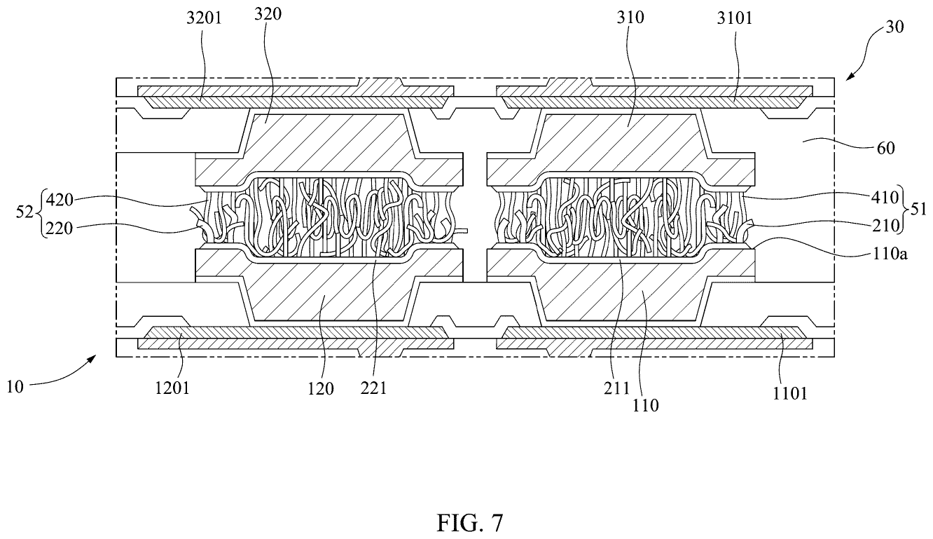

FIG. 7 is a cross-section of a portion of a package structure in accordance with some arrangements of the present disclosure. In some arrangements, FIG. 7 illustrates a cross-section of the structure of the portion A of the package structure 1 illustrated in FIG. 1A. The structure illustrated in FIG. 7 is similar to that in FIG. 3A, and the differences therebetween are described as follows.

The wires 210 illustrated in FIG. 7 are similar to the wires 210 illustrated in FIG. 3A, and the description thereof is omitted. In some arrangements, a density distribution of the wires 410 is different from a density distribution of the wires 210. In some arrangements, a density of the wires 410 is substantially uniform. In some arrangements, a length distribution of the wires 410 is different from a length distribution of the wires 210. In some arrangements, the length of the wires 210 decreases from the region R11 toward the region R13, and the wires 410 have a substantially uniform length. In some arrangements, a width distribution of the wires 410 is different from a width distribution of the wires 210. In some arrangements, the wires 410 have a substantially uniform width.

The wires 220 illustrated in FIG. 7 are similar to the wires 220 illustrated in FIG. 3A, and the description thereof is omitted. In some arrangements, a density distribution of the wires 420 is different from a density distribution of the wires 220. In some arrangements, a density of the wires 420 is substantially uniform. In some arrangements, a length distribution of the wires 420 is different from a length distribution of the wires 220. In some arrangements, the length of the wires 220 decreases from the region R21 toward the region R23, and the wires 420 have a substantially uniform length. In some arrangements, a width distribution of the wires 420 is different from a width distribution of the wires 220. In some arrangements, the wires 420 have a substantially uniform width.

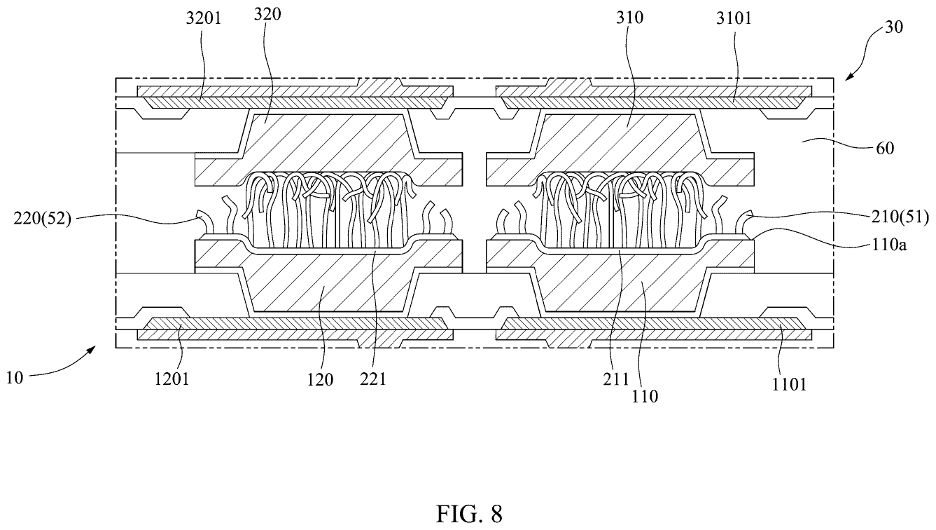

FIG. 8 is a cross-section of a portion of a package structure in accordance with some arrangements of the present disclosure. In some arrangements, FIG. 8 illustrates a cross-section of the structure of the portion A of the package structure 1 illustrated in FIG. 1A. The structure illustrated in FIG. 8 is similar to that in FIG. 3A, and the differences therebetween are described as follows.

The wires 210 and 220 illustrated in FIG. 7 are similar to the wires 210 and 220 illustrated in FIG. 3A, and the description thereof is omitted. In some arrangements, the wires 210 directly contact the conductive pad 110 and the conductive pad 310. In some arrangements, the wires 220 directly contact the conductive pad 120 and the conductive pad 320.

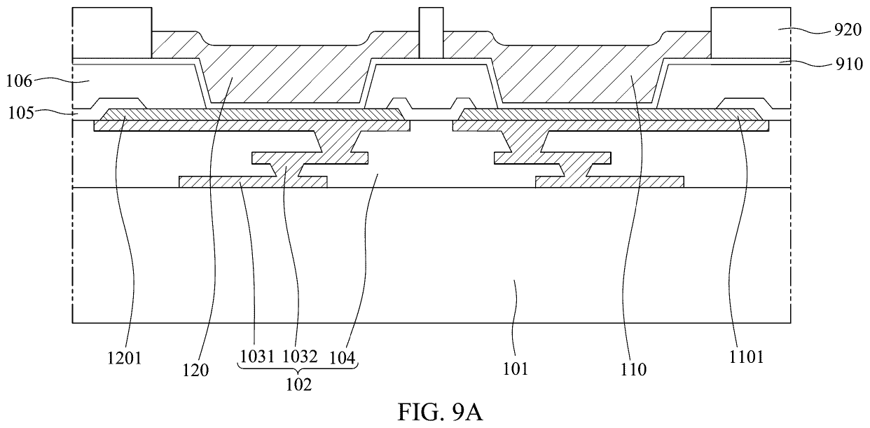

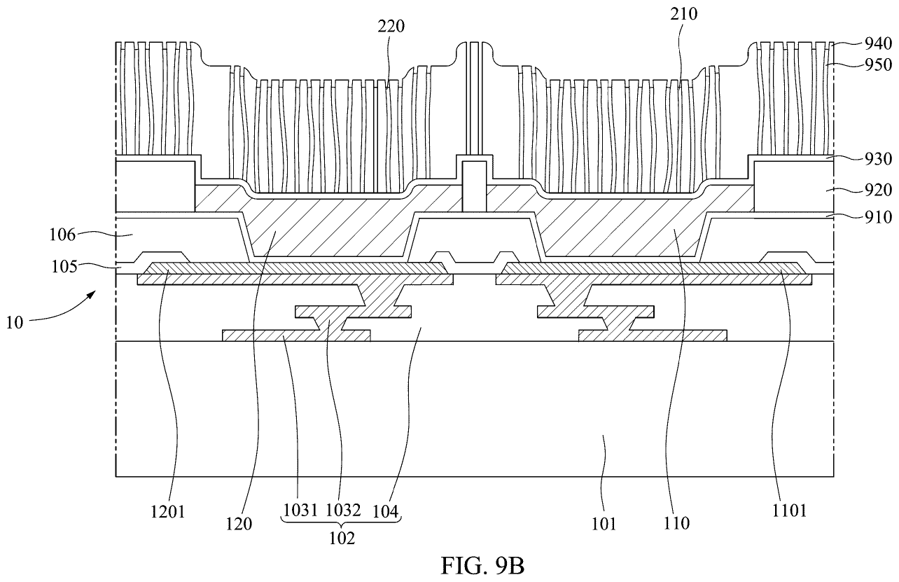

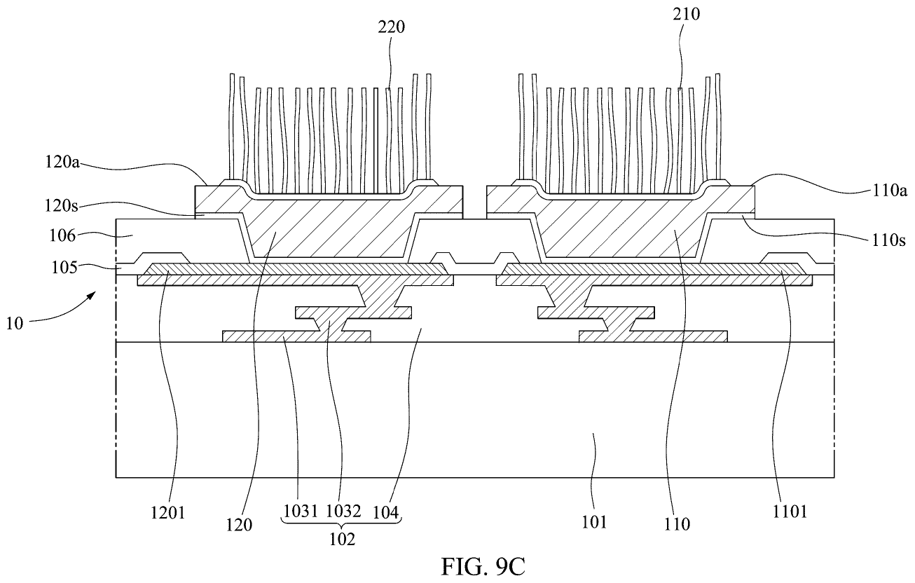

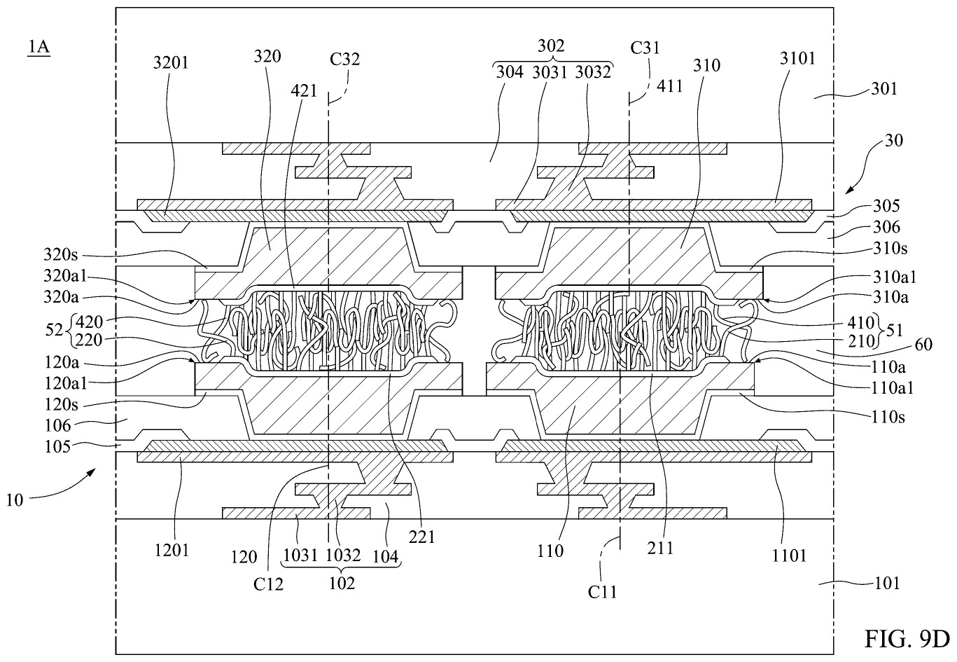

FIG. 9A, FIG. 9B, FIG. 9C, and FIG. 9D illustrate various stages of an example of a method for manufacturing a package structure 1A in accordance with some arrangements of the present disclosure.

Referring to FIG. 9A, a substrate 10 including a device layer 101, an interconnection structure 102, conductive layers 1101 and 1201, a passivation layer 105, a dielectric layer 106, and conductive pads 110 and 120 may be provided. In some arrangements, the interconnection structure 102 including a dielectric layer 104, conductive traces 1031, and conductive vias 1032 is formed on the device layer 101. In some arrangements, the conductive layers 1101 and 1201 are then formed on the conductive traces 1031, and the passivation layer 105 is formed on the interconnection structure 102 and having openings exposing the conductive layers 1101 and 1201. In some arrangements, the dielectric layer 106 is then formed on the passivation layer 105 and having openings exposing the conductive layers 1101 and 1201. In some arrangements, a seed layer 910 is then formed on the passivation layer 105 and the exposed conductive layers 1101 and 1201, and a photoresist layer 920 is formed on portions of the seed layer 910 and defining openings that expose other portions of the seed layer 910 over the conductive layers 1101 and 1201. Next, in some arrangements, a conductive material is disposed or formed in the openings of the photoresist layer 920 to form the conductive pads 110 and 120. The conductive material may be disposed or formed by plating. In some arrangements, the top surfaces of the conductive pads 110 and 120 are lower than the top surface of the photoresist layer 920 with respect to a top surface of the dielectric layer 106.

Referring to FIG. 9B, a seed layer 930 may be formed on the top surfaces of the conductive layers 110 and 120 and the photoresist layer 920, a porous template 940 may be formed on the seed layer 930, and a conductive material may be disposed or formed in the pores of the porous template 940 to form wires 210, 220, and 950. In some arrangements, a metal substrate may be formed on the seed layer 930, and an electrochemical technique, such as an anodizing technique, may be used to form pores in the metal substrate so as to form the porous template 940 having a plurality of pores. The porous template 940 may be referred to as an anodic aluminum oxide (AAO) substrate. In some arrangements, less pores or even no pore may be formed in the regions of the porous template 940 over the stepped profiles defined by the top surfaces of the conductive layers 110 and 120 and the top surface of the photoresist layer 920. In some arrangements, since less pores or even no pores are formed over the stepped profiles defined by the top surfaces of the conductive layers 110 and 120 and the top surface of the photoresist layer 920, less wires or even no wires may be formed over edges of the top surfaces of the conductive layers 110 and 120.

Referring to FIG. 9C, the photoresist layer 920 and portions of the seed layer 910 under the photoresist layer 920 may be removed to form seed layers 211 and 221. In some arrangements, the wires 950 that are formed over the photoresist layer 920 are removed along with the photoresist layer 920. In some arrangements, portions of the seed layer 910 under the photoresist layer 920 are removed to form the seed layers 110s and 120s. As such, the substrate 10 including the conductive layers 110 and 120 and the wires 210 and 220 may be formed.

Referring to FIG. 9D, operations similar to those illustrated in FIGS. 9A-9C may be performed to form a substrate 30 including conductive layers 310 and 320 and wires 410 and 420, and the substrate 30 may be connected or bonded to the substrate 10 through the conductive layers 110, 120, 310, and 320 and the wires 210, 220, 410, and 420. Next, an encapsulant 60 may be disposed or formed between the substrates 10 and 30. As such, the package structure 1A may be formed. In some arrangements, the package structure 1A is a portion of the package structure 1 illustrated in FIG. 1A. In some arrangements, FIG. 9A, FIG. 9B, FIG. 9C, and FIG. 9D show portions of structures that illustrate various stages of an example of a method for manufacturing the package structure 1 illustrated in FIG. 1A.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A bonding structure, comprising:
a first pad having a top surface including a first region and a second region, wherein the second region is closer to an edge of the top surface of the first pad than the first region is; and
a plurality of first wires on the top surface of the first pad, wherein a number of the first wires on the first region is greater than a number of the first wires on the second region.

2. The bonding structure as claimed in claim 1, wherein the first wires have a first wiring density on the first region and a second wiring density on the second region less than the first density.

3. The bonding structure as claimed in claim 1, wherein a wiring density of the first wires decreases from the first region toward the second region.

4. The bonding structure as claimed in claim 1, wherein the second region of the top surface of the first pad is free of the plurality of first wires.

5. The bonding structure as claimed in claim 1, wherein a length of the first wires on the second region of the top surface is less than a length of the first wires on the first region of the top surface.

6. The bonding structure as claimed in claim 1, wherein an elevation of the first region is higher than an elevation of the second region with respect to a bottom surface of the first pad.

7. The bonding structure as claimed in claim 1, further comprising:
a second pad over the first pad; and
a plurality of second wires on the top surface of the second pad and electrically connected to the plurality of first wires, wherein a portion of the plurality of first wires is spaced apart from a portion of the plurality of second wires.

8. The bonding structure as claimed in claim 7, wherein the portion of the plurality of second wires is over and spaced apart from the plurality of first wires.

9. The bonding structure as claimed in claim 7, wherein the first wires comprise a first curved portion, and the first curved portion extends from the first region to the second region of the top surface of the first pad.

10. A package structure, comprising:
a first substrate comprising a first pad and a second pad;
a second substrate comprising a third pad and a fourth pad;
a plurality of first wires connecting the first pad to the third pad; and
a plurality of second wires connecting the second pad to the fourth pad, wherein a wiring density distribution of the first wires is different from a wiring density distribution of the second wires.

11. The package structure as claimed in claim 10, wherein a length distribution of the first wires is different from a length distribution of the second wires.

12. The package structure as claimed in claim 11, wherein a distance between the first pad and the third pad is different from a distance between the second pad and the fourth pad.

13. The package structure as claimed in claim 11, wherein a central axis of the first pad is misaligned with a central axis of the third pad.

14. The package structure as claimed in claim 10, further comprising a plurality of third wires connecting the third pad to the first wires, wherein a wiring density distribution of the third wires is different from the wiring density distribution of the first wires.

15. The package structure as claimed in claim 11, wherein the first wires directly contact the first pad and the third pad.

16. A package structure, comprising:
a first substrate comprising a first pad and a second pad adjacent to the first pad;
a second substrate comprising a third pad; and
a wire bundle structure between the first pad and the third pad, wherein the wire bundle structure comprises a dense portion configured to electrically connect the first pad to the third pad and a porous portion configured to reduce an electrical transmission between the wire bundle structure and the second pad when the first pad is electrically connected to the third pad through the wire bungle structure.

17. The package structure as claimed in claim 16, wherein the porous portion is between the dense portion and the second pad.

18. The package structure as claimed in claim 17, wherein a boundary of the dense portion is recessed from an edge of the first pad by at least 20% of a width of the first pad.

19. The package structure as claimed in claim 17, wherein the porous portion is on a peripheral region of a surface of the first pad.

20. The package structure as claimed in claim 16, wherein the dense portion covers at least 50% of an area of a surface of the first pad.
